(19) United States
(12) Patent Application Publication
(10) Pub. No.: US 2025/0108414 A1
(43) Pub. Date: Apr. 3, 2025

(54) CLEANING APPARATUS FOR WAFER STORAGE CONTAINER

(71) Applicant: SHIBAURA MECHATRONICS CORPORATION, Kanagawa (JP)

(72) Inventors: Junji ISHIHARA, Kanagawa (JP); Hisaaki MIYASAKO, Kanagawa (JP); Yukinobu NISHIBE, Kanagawa (JP)

(21) Appl. No.: 18/897,666

(22) Filed: Sep. 26, 2024

(30) Foreign Application Priority Data
Sep. 29, 2023 (JP) 2023-170840

(51) Int. Cl. B08B 9/20; B65G 47/90; H01L 21/673

(52) U.S. Cl. CPC B08B 9/205; B65G 47/90; B08B 2209/08; H01L 21/6735

(57) ABSTRACT

According to one embodiment of the present disclosure, a wafer storage container cleaning apparatus includes a cleaning chamber that cleans a wafer storage container including a shell including an opening on one surface and a gripped portion on another surface crossing the one surface with the opening, and a door detachable from the opening; and a transfer robot including a robot hand that individually grips the shell and the door. The robot hand includes a shell gripping portion including a pair of first gripping claws that are movable toward and away from each other along a first straight line; and a door gripping portion including a pair of second gripping claws movable toward and away from each other along a second straight line intersecting the first straight line in a top view. The cleaning chamber cleans the shell with the opening facing downward.

### CROSS-REFERENCE TO RELATED APPLICATIONS

This application is based on and claims priority from Japanese Patent Application No. 2023-170840 filed on Sep. 29, 2023 with the Japan Patent Office, the disclosure of which is incorporated herein in its entirety by reference.

### TECHNICAL FIELD

The present disclosure relates to a cleaning apparatus for a wafer storage container.

### BACKGROUND

A front opening unified pod (FOUP) is known as a semiconductor wafer storage container used in the semiconductor wafer manufacturing process. The FOUP includes a shell (container body) with an opening and a door (opening/closing lid) attached to the opening of the shell. The inside of the shell serves as a storage space with a plurality of shelves formed to hold a plurality of wafers.

Such a FOUP is used when transferring a semiconductor wafer, on which semiconductor devices are formed through various processing steps (e.g., resist coating, exposure/development, etching (film formation), resist peeling, cleaning, etc.), between processing steps. That is, the semiconductor wafer is transferred between processing steps while being held in the FOUP.

When the FOUP is used repeatedly, particles and chemical contaminants may adhere to the inner walls of the FOUP (the walls that define the space in which the wafers are stored). When the contaminants adhere to the semiconductor wafers stored in the FOUP, there is a concern that the yield of semiconductor devices would be decreased. For this reason, after the FOUP has been used several times, the FOUP is cleaned in order to be restored to a clean state.

As a technique for cleaning a FOUP, for example, a wafer storage container cleaning apparatus has been proposed in which the shell and the door of a FOUP are individually cleaned in a single cleaning chamber.

In addition, the transfer robot loads the shell and the door of a FOUP into the cleaning chamber, and unloads the shell and the door from the cleaning chamber. See, for example, Japanese Patent Laid-Open Publication No. 2005-109523.

### SUMMARY

In such a wafer storage container cleaning apparatus, the throughput needs to be improved so as not to impede the production efficiency of semiconductor devices. The same is true for other types of wafer storage container cleaning apparatuses than FOUPs (e.g., front opening shipping boxes (FOSBs))

The present disclosure provides a wafer storage container cleaning apparatus capable of efficiently cleaning a wafer storage container.

A wafer storage container cleaning apparatus according to one embodiment of the present disclosure includes a cleaning chamber that cleans a wafer storage container including a shell having a hexahedral outer shape and including an opening on one surface and a gripped portion on another surface crossing the surface with the opening, and a door detachable from the opening; and a transfer robot including a robot hand that individually grips the shell and the door, and configured to individually load the shell and the door into the cleaning chamber and individually unload the shell and the door from the cleaning chamber.

The robot hand includes a shell gripping portion including a pair of first gripping claws movable toward and away from each other along a first straight line, and configured to grip the gripped portion using the pair of first gripping claws; and a door gripping portion including a pair of second gripping claws movable toward and away from each other along a second straight line intersecting the first straight line in a top view, and configure to grip the door using the pair of second gripping claws. The cleaning chamber cleans the shell with the opening facing downward.

According to one embodiment of the present disclosure, it is possible to provide a wafer storage container cleaning apparatus capable of efficiently cleaning a wafer storage container.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 is a plan view illustrating an example of a schematic configuration of a wafer storage cleaning apparatus according to an embodiment.

FIG. 2 is a cross-sectional view taken along line X-X of the wafer storage container cleaning apparatus according to a first embodiment.

FIG. 3 is a schematic view illustrating an example of the configuration of a transfer robot according to the first embodiment.

FIG. 4 is a cross-sectional view illustrating an example of the internal configuration of a robot hand according to the first embodiment.

FIG. 5 is a cross-sectional view taken along line Y-Y in FIG. 4.

FIG. 6 is a view illustrating an example of a base body according to the first embodiment.

FIG. 7 is a view illustrating an example of a state where the robot hand according to the first embodiment grips a flange.

FIG. 8 is a cross-sectional view illustrating an example of the internal configuration of the robot hand according to the first embodiment.

FIG. 9 is a view for explaining the door and the gripping claws in the first and second embodiments.

FIG. 10 is a view for explaining the door and the gripping claws in the first and second embodiments.

FIG. 11 is a view for explaining the door and the gripping claws in the first and second embodiments.

FIG. 12 is a view for explaining the door and the gripping claws in the first and second embodiments.

FIG. 13 is a view for explaining the door and the gripping claws in the first and second embodiments.

FIG. 14 is a view illustrating an example of a state where a pair of gripping claws grip a door when a protrusion is provided on the outer peripheral surface of the door.

FIG. 15 is a perspective view of a gripping claw according to a modification.

FIG. 16 is a view illustrating an example in which a pair of gripping claws grip a door.

FIG. 17 is a view illustrating an example in which a pair of gripping claws grip a door.

FIG. 18 is a view illustrating an example in which a pair of gripping claws grip a door.

FIG. 19 is a view illustrating an example of a state where a pair of gripping claws grip a door when a protrusion is provided on the outer peripheral surface of the door.

### DESCRIPTION OF EMBODIMENTS

In the following detailed description, reference is made to the accompanying drawing, which form a part hereof. The illustrative embodiments described in the detailed description, drawings, and claims are not meant to be limiting. Other embodiments may be utilized, and other changes may be made without departing from the spirit or scope of the subject matter presented here.

Hereinafter, embodiments of a wafer storage container cleaning apparatus disclosed herein are described in detail with reference to the accompanying drawings. The wafer storage container cleaning apparatus disclosed herein is not limited to the following embodiments. In addition, the respective embodiments and modifications may be appropriately combined within a range in which no contradiction occurs. In this embodiment, a case in which at least four processing chambers of the wafer storage container cleaning apparatus are cleaning chambers (cleaning processing chambers) is described as an example.

### (First Embodiment)

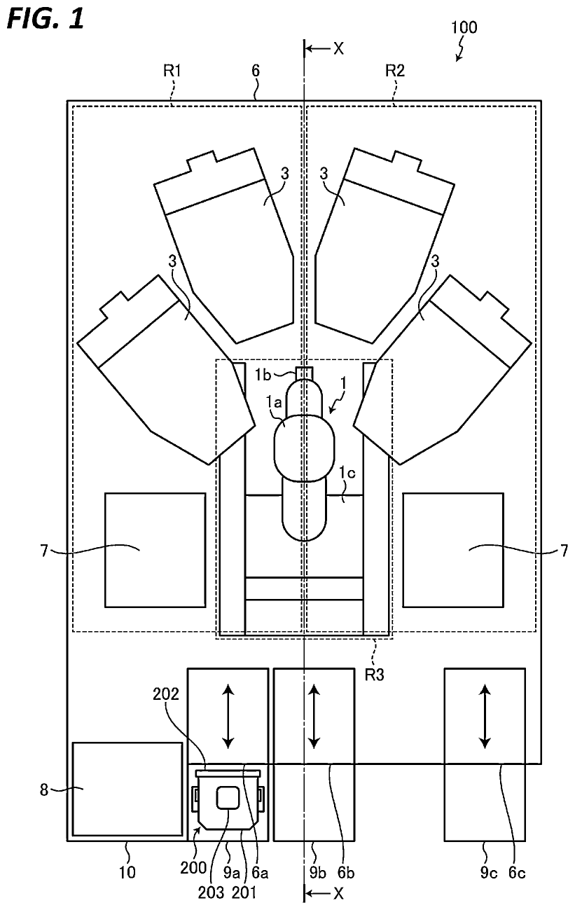

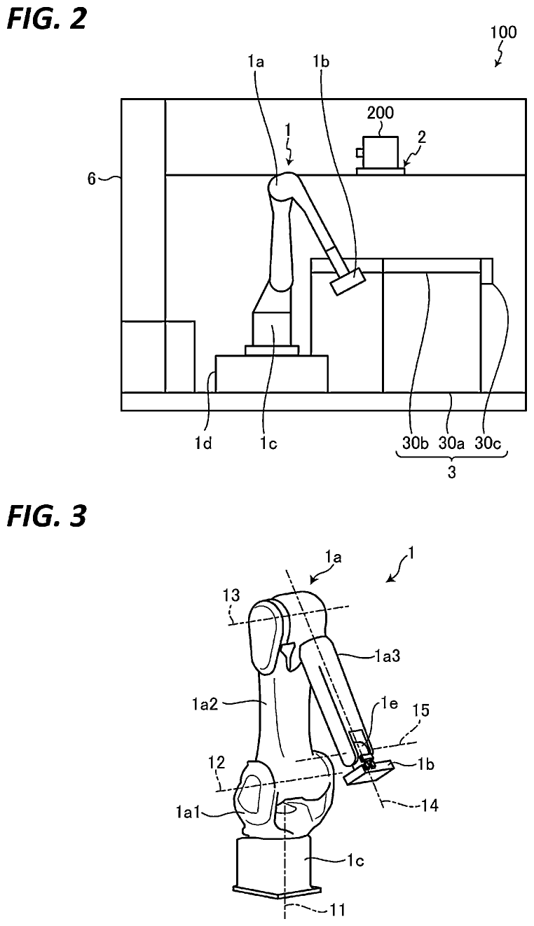

FIG. 1 is a plan view illustrating an example of a schematic configuration of a wafer storage cleaning apparatus 100 according to an embodiment. FIG. 2 is a cross-sectional view taken along the line X-X of FIG. 1. The wafer storage container cleaning apparatus 100 is installed, for example, in a factory that manufactures semiconductor wafers, and cleans wafer storage containers. As illustrated in FIGS. 1 and 2, the wafer storage container cleaning apparatus 100 includes a transfer robot 1, a lock/unlock stage 2, a cleaning chamber 3, a housing 6, a vacuum processing chamber 7, a control unit 8, a first load/unload port 9a, a second load/unload port 9b, a third load/unload port 9c, and an input interface 10.

In the embodiment, a wafer storage container 200 is, for example, a FOUP or FOSB, and includes a shell 201 as a container body and a door 202. The shell 201 has a hexahedral shape. And, the shell 201 has a rectangular opening on one side. In addition, the shell 201 has a storage space for storing semiconductor wafers. The storage space is located inside the opening and communicates with the opening. The door 202 is lockable/unlockable with respect to the shell 201. In this way, the door 202 has a rectangular shape with a size corresponding to the opening of the shell 201, and is detachable from the opening. The door 202 is an example of a door unit. In addition, the shell 201 is provided with a flange 203. For example, the shell 201 has a flange 203 on another side that is perpendicular (intersecting) to the side having the opening. The flange 203 is a portion that is gripped (held) when the wafer storage container 200 is transferred by an overhead hoist transport (OHT) or a transfer robot 1, and is formed in a square plate shape. The flange 203 is an example of a gripped portion.

A transfer robot 1, a lock/unlock stage 2, a cleaning chamber 3, a maintenance area 4, a cover 5, a vacuum processing chamber 7, and a control unit 8 are provided inside the housing 6. Meanwhile, a first load/unload port 9a, a second load/unload port 9b, and a third load/unload port 9c are provided across the inside and outside of the housing 6.

The first load/unload port 9a loads the wafer storage container 200 to be cleaned, which is disposed on a portion of the first load/unload port 9a outside the housing 6, into the housing 6.

For example, the wafer storage container 200, which is transferred with the flange 203 held by the OHT, is disposed on a portion of the first load/unload port 9a outside the housing 6. For example, as illustrated in FIG. 1, the wafer storage container 200 is disposed on the first load/unload port 9a such that the door 202 of the wafer storage container 200 faces the housing 6. When the wafer storage container 200 is disposed on the first load/unload port 9a in this manner, a shutter provided on the opening 6a of the housing 6 is raised. As a result, the wafer storage container 200 may be loaded into the housing 6 from the opening 6a. Then, the wafer storage container 200 is slid in a direction toward the inside by a slide device of the first load/unload port 9a, and is loaded into the housing 6.

In addition, the first load/unload port 9a unloads the cleaned and vacuum-dried wafer storage container 200, which is disposed by the transfer robot 1 on a portion of the first load/unload port 9a inside the housing 6, to the outside of the housing 6.

For example, after vacuum-drying, the wafer storage container 200, whose shell 201 and door 202 are connected at the lock/unlock stage 2, is transferred by the transfer robot 1 and disposed in the first load/unload port 9a inside the housing 6. When the wafer storage container 200 is disposed on the first load/unload port 9a in this manner, a shutter provided on the opening 6a of the housing 6 is raised. As a result, the wafer storage container 200 may be unloaded from the opening 6a to the outside of the housing 6. Then, the wafer storage container 200 is slid in a direction toward the outside by a slide device of the first load/unload port 9a, and is unloaded to the outside of the housing 6.

Like the first load/unload port 9a, the second load/unload port 9b, may load and unload the wafer storage container 200 through the opening 6b of the housing 6. Also, the third load/unload port 9c may be configured to load and unload the wafer storage container 200 through the opening 6c of the housing 6 in the same manner as the first load/unload port 9a.

The transfer robot 1 is a vertical articulated robot, and transfers the wafer storage container 200 to each part while gripping the flange 203 of the wafer storage container 200. FIG. 3 is a schematic view illustrating an example of the configuration of the transfer robot 1 according to the first embodiment. As illustrated in FIGS. 2 and 3, the transfer robot 1 includes a robot arm 1a, a robot hand 1b, a base 1c, a moving device 1d, and a wrist 1e. The transfer robot 1 transfers the wafer storage container 200 to each part by extending and retracting the robot arm 1a and rotating the robot arm 1a while the robot arm la is supported by the base 1c and the robot hand 1b on the tip of the robot arm la grips the flange 203.

The moving device 1d includes a servo motor and a ball screw mechanism (not illustrated), and may move the base 1c in a front-rear direction (an up-down direction in the figure) within a moving region R3 illustrated in FIG. 1.

As illustrated in the example of FIG. 3, the robot arm 1a of the transfer robot 1 includes a pivot support member 1a1, a first arm 1a2, and a second arm 1a3.

The lower end portion of the pivot support member 1a1 is supported by the upper portion of the base 1c in a state of being pivotable around an axis 11 extending in the vertical direction (vertical axis). In addition, the first arm 1a2 is connected to the upper end portion of the pivot support member 1a1 in a state of being pivotable around an axis 12 extending in the horizontal direction (horizontal axis). In addition, the second arm 1a3 is connected to the other end portion of the first arm 1a2 in a state of being pivotable around a horizontal axis 13. In addition, the wrist 1e is connected to the other end portion of the second arm 1a3 in a state of being pivotable around a horizontal axis 15. In addition, the robot hand 1b is connected to the tip of the wrist 1e in a state of being pivotable around an axis 14 perpendicular to the horizontal axis 15. With the above-mentioned configuration, the transfer robot 1 may move the robot hand 1b to various positions.

In the lock/unlock stage 2, an unlocking process for separating the wafer storage container 200 into the shell 201 and the door 202, and a locking process for connecting the shell 201 and the door 202 are performed. A latch key is provided on the lock/unlock stage 2, and the unlocking and locking processes of the wafer storage container 200 are performed by rotating the latch key while being inserted into the key hole formed in the door 202 of the wafer storage container 200. For example, the wafer storage container 200 loaded into the housing 6 is transferred to the lock/unlock stage 2 by the transfer robot 1, and the unlocking process is performed in the lock/unlock stage 2. Then, the transfer robot 1 loads the shell 201 and the door 202 into the cleaning chamber 3 separately. In addition, when the temporary drying of the wafer storage container 200 is completed in the cleaning chamber 3, the transfer robot 1 unloads the shell 201 and the door 202 individually from the cleaning chamber 3, and transfers the shell 201 and the door 202 individually to the vacuum processing chamber 7. Furthermore, in the lock/unlock stage 2, the vacuum-dried shell 201 and door 202 are transferred by the transfer robot 1, and the locking process is performed.

In the wafer storage container cleaning apparatus 100 of this embodiment, the lock/unlock stage 2 is provided on a plate-shaped support member located within the housing 6 at a position higher than the installation surfaces of the cleaning chamber 3, vacuum processing chamber 7, and the like.

The cleaning chamber 3 is a chamber for cleaning the wafer storage container 200. For example, the shell 201 and the door 202 are transferred separately to the cleaning chamber 3 by the robot 1. Then, the cleaning chamber 3 performs a cleaning process on the wafer storage container 200 while holding the shell 201 and the door 202 separately. For example, as illustrated in FIG. 2, the cleaning chamber 3 includes a cleaning chamber body 30a having an opening on the top surface, a top lid 30b capable of opening and closing the opening of the cleaning chamber body 30a, and a top lid opening and closing driving mechanism 30c for opening and closing the top lid 30b. In the cleaning chamber 3, the top lid 30b holds the door 202, and the shell 201 is disposed on a rotary table (not illustrated) provided on the cleaning chamber body 30a. Then, in the cleaning chamber 3, the shell 201 and the door 202 are rotated by a rotating mechanism (not illustrated), and a cleaning liquid (e.g., deionized water) is discharged from a cleaning liquid nozzle onto each of the shell 201 and the door 202, thereby cleaning the wafer storage container 200. In the cleaning chamber 3, the shell 201 is arranged with the opening of the shell 201 facing downward in consideration of the dischargeability of the cleaning liquid, but the orientation in which the shell 201 is arranged is not limited thereto.

When cleaning of the wafer storage container 200 is completed in the cleaning chamber 3, the cleaning chamber 3 then rotates the shell 201 and the door 202 in the cleaning chamber 3 and blows dry air onto the shell 201 and the door 202 to perform drying. The drying in the cleaning chamber 3 is a process for substantially drying the cleaning liquid adhering to the wafer storage container 200 (temporary drying). When the temporary drying of the wafer storage container 200 is completed in the cleaning chamber 3, the transfer robot 1 transfers the shell 201 and the door 202 in the cleaning chamber 3 separately to the vacuum processing chamber 7.

As illustrated in FIG. 1, the wafer storage container cleaning apparatus 100 has four cleaning chambers 3, two of which are arranged in each of the first region R1 and the second region R2.

The vacuum processing chamber 7 is a chamber for vacuum-drying (main drying) the wafer storage container 200. For example, the vacuum processing chamber 7 includes a vacuum chamber body, an opening/closing lid, a heater, and a pressure reducing device capable of evacuating the inside of the vacuum processing chamber 7. The vacuum processing chamber 7 is configured such that the shell 201 and the door 202 are loaded into the vacuum chamber body by the transfer robot 1, and in a state where the opening of the vacuum chamber body is closed by the opening/closing lid, the shell 201 and the door 202 are vacuum-dried by heating with the heater while evacuating with the pressure reducing device.

The control unit 8 controls the overall operation of the wafer storage container cleaning apparatus 100. For example, the control unit 8 controls the transfer robot 1, the lock/unlock stage 2, the cleaning chamber 3, the vacuum processing chamber 7, the first load/unload port 9a, the second load/unload port 9b, and the third load/unload port 9c, thereby operating the transfer robot 1, the lock/unlock stage 2, the cleaning chamber 3, the vacuum processing chamber 7, the first load/unload port 9a, the second load/unload port 9b, and the third load/unload port 9c as described above.

For example, the control unit 8 includes a central processing unit (CPU), a read only memory (ROM), a random access memory (RAM), a hard disk drive (HDD), and a communication interface. These are connected via an internal bus.

The CPU executes various processes while using the memory area of the RAM as a temporary storage area for data used in the various processes. The ROM and HDD store programs for executing various processes, and various databases and tables used when executing the various processes.

The communication interface is an interface for communicating with the above-mentioned units of the wafer storage container cleaning apparatus 100, and also for communicating with external devices connected to the wafer storage container cleaning apparatus 100 via a network. For example, the communication interface is a network interface card.

The input interface 10 receives input operations of various instructions and various information from a worker P. Specifically, the input interface 10 is connected to the control unit 8, and transmits the input operations received from the worker P to the control unit 8. For example, the input interface 10 is a mouse, a keyboard, a touch panel, or the like.

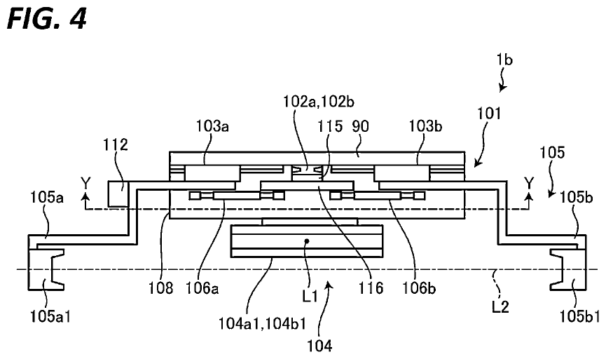

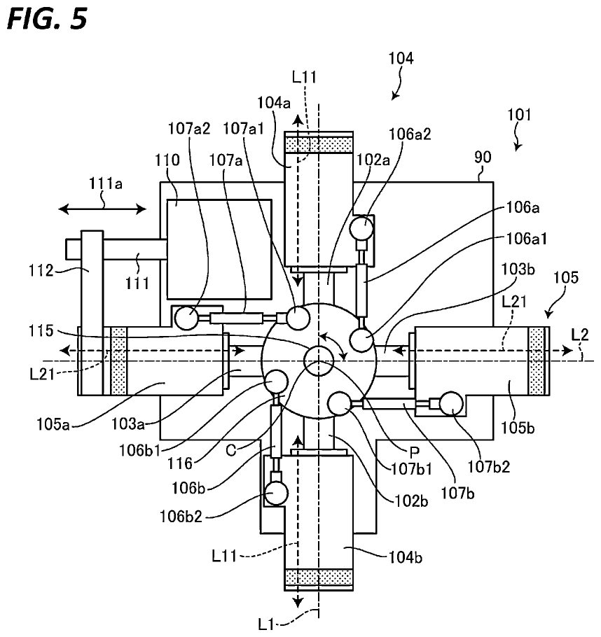

Next, an example of the robot hand 1b according to the embodiment is described. FIG. 4 is a cross-sectional view illustrating an example of the internal configuration of the robot hand 1b according to the first embodiment. FIG. 5 is a cross-sectional view taken along line Y-Y in FIG. 4.

As illustrated in FIGS. 4 and 5, the robot hand 1b includes a base 90, a gripping portion driving mechanism 101, a shell gripping portion 104, and a door gripping portion 105. The gripping portion driving mechanism 101, the shell gripping portion 104, and the door gripping portion 105 are each disposed on the base 90. In the embodiment, the robot hand 1b grips the shell 201 and the door 202 individually. The robot hand 1b is an example of a gripping mechanism.

The shell gripping portion 104 grips the square flange 203 of the shell 201. The shell gripping portion 104 includes a pair of gripping claws 104a1 and 104b1 and a pair of arm blocks 104a and 104b. The gripping claw 104a1 is provided at one end of the arm block 104a, and the gripping claw 104b1 is provided at one end of the arm block 104b. The shell gripping portion 104 grips the flange 203 using the pair of gripping claws 104a1 and 104b1. Specifically, the pair of gripping claws 104a1 and 104b1 grip the flange 203 by clamping the flange 203. The gripping claws 104a1 and 104b1 are formed, for example, to have substantially the same length as the side of the flange 203 to be gripped. The shell gripping portion 104 is, an example of a shell gripping portion.

The door gripping portion 105 grips the rectangular door 202 that is larger than the flange 203. The door gripping portion 105 includes a pair of gripping claws 105a1 and 105b1 and a pair of arm blocks 105a and 105b. The gripping claw 105a1 is provided at one end of the arm block 105a, and the gripping claw 105b1 is provided at one end of the arm block 105b. The door gripping portion 105 grips the door 202 using the pair of gripping claws 105a1 and 105b1. Specifically, the pair of gripping claws 105a1 and 105b1 grip the door 202 by clamping the door 202. Since the gripping claws 105a1 and 105b1 hold, for example, only the central portion of the door 202, the gripping claws 105a1 and 105b1 are formed to have a length shorter than the gripping claws 104a1 and 104b1. In addition, since the pair of gripping claws 105a1 and 105b1 may grip the rectangular door 202 which is larger than the flange 203, the distance between the pair of gripping claws 105a1 and 105b1 is wider than the distance between the pair of gripping claws 104a1 and 104b1.

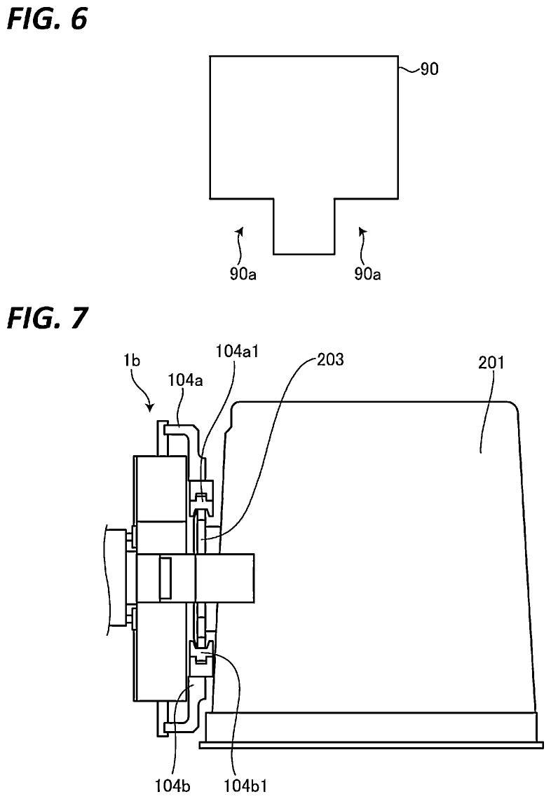

The base 90 is provided with a gripping portion driving mechanism 101. FIG. 6 is a view illustrating an example of the base 90 according to the first embodiment. As illustrated in FIG. 6, the base 90 is formed in a shape having notches 90a formed by cutting out two adjacent corners of a rectangle in a square shape when viewed from above (convex shape). For example, when the shell 201 is transferred to the lock/unlock stage 2 in an orientation in which the notches 90a are located on the lower side, it is possible to prevent the robot hand 1b from interfering with the lock/unlock stage 2. The robot hand 1b may be prevented from interfering with the cleaning chamber 3 not only when transferring the shell 201 to the lock/unlock stage 2, but also when disposing (loading) the shell 201 into the cleaning chamber 3 or removing (unloading) the shell 201 from the cleaning chamber 3.

The gripping portion driving mechanism 101 drives the shell gripping portion 104 to cause the shell gripper 104 to grip the flange 203 of the shell 201, and drives the door gripping portion 105 to cause the door gripping portion 105 to grip the door 202. The gripping portion driving mechanism 101 includes linear guides 102a, 102b, 103a, and 103b, a support shaft 115, a pivoting member 116, four connecting members 106a, 106b, 107a, and 107b, an air cylinder 110, a rod portion 111, and a connecting portion 112.

Each of the linear guides 102a and 102b supports each of the arm blocks 104a and 104b such that each of the arm blocks 104a and 104b move toward and away from each other along a first straight line L1, which is a virtual line. As a result, a pair of gripping claws 104a1 and 104b1 provided on the two arm blocks 104a and 104b may move toward and away from each other as indicated by the double-headed arrow L11. In this manner, the linear guides 102a and 102b support the pair of gripping claws 104a1 and 104b1 so as to be movable in a direction along the first straight line L1. The linear guides 102a and 102b are an example of a first guide. Also, the gripping claws 104a1 and 104b1 are an example of first gripping claws.

Each of the linear guides 103a and 103b supports each of the arm blocks 105a and 105b such that each of the arm blocks 105a and 105b move toward and away from each other along a second straight line L2, which is a virtual line perpendicular to the first straight line L1 in a top view. As a result, a pair of gripping claws 105a1 and 105b1 provided on the two arm blocks 105a and 105b may move toward and away from each other as indicated by the double-headed arrow L21. In this manner, the linear guides 103a and 103b support the pair of gripping claws 105a1 and 105b1 so as to be movable in a direction along the first straight line L2. The linear guides 103a and 103b are an example of a second guide. Also, the gripping claws 105a1 and 105b1 are an example of second gripping claws.

Although an example has been given of the case where the second straight line L2 is perpendicular to the first straight line L1 when viewed from above, the present disclosure is not limited to the case where the second straight line L2 is perpendicular to the first straight line L1 when viewed from above, and the second straight line L2 may intersect the first straight line L1 when viewed from above.

In the embodiment, as illustrated in FIG. 5, the first straight line L1 and the second straight line L2 intersect at the support shaft 115 when viewed from above. Therefore, the shell gripping portion 104 and the door gripping portion 105 are disposed in an intersecting relationship with the support shaft 115 as the center.

The air cylinder 110 drives the rod portion 111 to advance and retreat (reciprocate) along the second straight line L2 under the control of the control unit 8. Accordingly, the rod portion 111 moves in two directions indicated by the double-headed arrow 111a along the second straight line L2. The direction along the second straight line L2, the two directions indicated by the double-headed arrow L21, and the two directions indicated by the double-headed arrow 111a are parallel to each other.

The connecting portion 112 is a member that connects the rod portion 111 and the arm block 105a. Since the rod portion 111 is connected to the arm block 105a via the connecting portion 112, when the rod portion 111 moves as described above, the arm block 105a moves in a direction along the second straight line L2 in conjunction with the movement of the rod portion 111.

The support shaft 115 is an axis provided at approximately the center of the base 90, and extends in a direction perpendicular to both the first straight line L1 and the second straight line L2 at a position P where the first straight line L1 and the second straight line L2 intersect in a top view. The pivoting member 116 is supported by the support shaft 115 so as to be pivotable around the support shaft 115. That is, in a top view, the position P coincides with the rotation center C. In this way, the pivoting member 116 is provided at the position P where the first straight line L1 and the second straight line L2 intersect in a top view, to be pivotable around the support shaft 115 perpendicular to both the first straight line L1 and the second straight line L2. The support shaft 115 is an example of an axis. In the embodiment, the pivoting member 116 is a disc-shaped member, but may be a member of another shape.

The four (plurality of) connecting members 106a, 106b, 107a, 107b connect the pair of gripping claws 104a1 and 104b1 and the pair of gripping claws 105a1 and 105b1 individually to the pivoting member 116 in a pivotable state. Specifically, a portion 106a1 on one end side of the connecting member 106a is connected to the pivoting member 116 in a pivotable state, and a portion 106a2 on the other end side of the connecting member 106a is connected to the arm block 104a in a pivotable state. In addition, a portion 106b1 on one end side of the connecting member 106b is connected to the pivoting member 116 in a pivotable state, and a portion 106b2 on the other end side of the connecting member 106b is connected to the arm block 106b in a pivotable state.

A portion 107a1 on one end side of the connecting member 107a is connected to the pivoting member 116 in a pivotable state, and a portion 107a2 on the other end side of the connecting member 107a is connected to the arm block 105a in a pivotable state. In addition, a portion 107b1 on one end side of the connecting member 107b is connected to the pivoting member 116 in a pivotable state, and a portion 107b2 on the other end side of the connecting member 107b is connected to the arm block 105b in a pivotable state.

The positions of a pair of ends 106a1 and 106b1 on the pivoting member 116 side of the pair of connecting members 106a, 106b connected to the pair of gripping claws 104a1 and 104b1 are symmetrical with respect to the rotation center C of the pivoting member 116. In addition, the positions of a pair of ends 107a1 and 107b1 on the pivoting member 116 side of the pair of connecting members 107a and 107b connected to the pair of gripping claws 105a1 and 105b1 are symmetrical with respect to the rotation center C of the pivoting member 116.

Further, in the embodiment, the four distances, i.e., the distance between the end 106a1 of the connecting member 106a and the rotation center C, the distance between the end 106b1 of the connecting member 106b and the rotation C, the distance between the end 107a1 of the connecting member 107a and the rotation center C, and the distance between the end 107b1 of the connecting member 107b and the rotation center C, are identical.

For these reasons, in the first embodiment, the stroke (opening/closing amount, movement amount) of the pair of gripping claws 104a1 and 104b1 is the same as the stroke of the pair of gripping claws 105a1 and 105b1.

Next, descriptions are made on an example of the operation of the gripping portion driving mechanism 101 when the shell gripping portion 104 grips the flange 203 of the shell 201, or the door gripper 105 grips the door 202. For example, the control unit 8 controls the transfer robot 1 such that the robot hand 1b approaches the flange 203 or the door 202 to a position where the flange 203 or the door 202 is able to be gripped by the robot hand 1b. As a result, the robot hand 1b approaches the flange 203 or the door 202 to a position where the flange 203 or the door 202 is able to be gripped by the robot hand 1b.

Then, in the state illustrated in FIG. 5, the control unit 8 controls the air cylinder 110 so as to retract the rod portion 111 toward the air cylinder 110. As a result, the rod portion 111 moves along the second straight line L2, which is the rightward direction in FIG. 5, of the two directions indicated by the double-headed arrow 111a. By the movement of the rod portion 111 in this way, the arm block 105a moves in conjunction with the movement of the rod portion 111, along the second straight line L2, in the rightward direction in FIG. 5 (in the direction approaching the support shaft 115).

When the arm block 105a moves to the rightward direction in FIG. 5, the pivoting member 116 connected to the arm block 105a by the connecting member 107a pivots clockwise in FIG. 5. When the pivoting member 116 pivots clockwise, the arm blocks 104a, 104b, and 105b connected by the connecting members 106a, 106b, and 107b also move in a direction approaching the support shaft 115. In this case, the pair of arm blocks 104a and 104b move closer to each other. In addition, the pair of arm blocks 105a and 105b also move closer to each other. When the pair of arm blocks 104a and 104b move closer to each other, the pair of gripping claws 104a1 and 104b1 move closer to each other in accordance with the movement of the pair of arm blocks 104a and 104b. Similarly, the pair of gripping claws 105a1 and 105b1 also move closer to each other. The pair of gripping claws 104a1 and 104b1 grip the flange 203 by clamping the flange 203, or the pair of gripping claws 105a1 and 105b1 grip the door 202 by clamping the door 202.

When the shell gripping portion 104 gripping the flange 203 of the shell 201 releases the flange 203, or when the door gripping portion 105 gripping the door 202 releases the door 202, the gripping portion driving mechanism 101 may perform the reverse operation to that described above. For example, the control unit 8 controls the air cylinder 110 such that the rod portion 111 protrudes from the air cylinder 110 (such that the rod portion 111 is returned to the state illustrated in FIG. 5). As a result, the rod portion 111 moves along the second straight line L2 in the leftward direction in FIG. 5 (the direction away from the support shaft 115) of the two directions indicated by the double-headed arrow 111a. As the rod portion 111 moves in this manner, the arm block 105a moves in the leftward direction in FIG. 5.

When the arm block 105a moves in the leftward direction in FIG. 5, the pivoting member 116 pivots counterclockwise in FIG. 5 in association with the movement of the arm block 105a. When the pivoting member 116 pivots counterclockwise, the arm blocks 104a, 104b, and 105b also move in a direction away from the support shaft 115. In this case, the pair of arm blocks 104a and 104b move away from each other. In addition, the pair of arm blocks 105a and 105b also move away from each other. When the pair of arm blocks 104a and 104b move away from each other, the pair of gripping claws 104a1 and 104b1 move away from each other in accordance with the movement of the pair of arm blocks 104a and 104b. Similarly, the pair of gripping claws 105a1 and 105b1 also move away from each other. As a result, the pair of gripping claws 104a1 and 104b1 release the flange 203, and the pair of gripping claws 105a1 and 105b1 release the door 202.

As described above, the air cylinder 110 moves one gripping claw 105a1 of the pair of gripping claws 104a1 and 104b1 and the pair of gripping claws 105a1 and 105b1, thereby moving all of the pair of gripping claws 104a1 and 104b1 and the pair of gripping claws 105a1 and 105b1. The gripping claw moved by the air cylinder 110 is not limited to the gripping claw 105a1, and may be the other gripping claws 104a1 and 104b1, 105b1. The air cylinder 110 is an example of a moving member (mover).

FIG. 7 is a view illustrating an example of a state where the robot hand 1b according to the first embodiment grips the flange 203. The example of FIG. 7 illustrates a case where the pair of gripping claws 104a1 and 104b1 grip the flange 203 by clamping the flange 203 in the up-down direction (vertical direction).

Here, when the pair of gripping claws 104a1 and 104b1 grip the flange 203 by clamping the flange 203 in the horizontal direction, there is a risk that the flange 203 may slip off the pair of gripping claws 104a1 and 104b1. For this reason, the pair of gripping claws 104a1 and 104b1 are required to clamp the flange 203 with a relatively strong force. Meanwhile, when the pair of gripping claws 104a1 and 104b1 grip the flange 203 by clamping the flange 203 in the vertical direction, the lower gripping claw of the pair of gripping claws 104a1 and 104b1 (the gripping claw 104b1 in the example of FIG. 7) supports the flange 203. For this reason, the magnitude of the force required when the pair of gripping claws 104a1 and 104b1 clamp the flange 203 in the vertical direction is smaller than the magnitude of the force required when clamping the flange 203 in the horizontal direction. Therefore, when the pair of gripping claws 104a1 and 104b1 clamp the flange 203 in the vertical direction, it is possible to reduce the force applied to the flange 203, thereby suppressing damage to the flange 203 and the gripping claws 104a1 and 104b1. In addition, the air cylinder 110 may be made smaller by the amount that the force clamping the flange 203 is able to be reduced, thereby enabling the weight of the robot hand 1b to be reduced.

Therefore, when the transfer robot 1 transfers the shell 201 into the cleaning chamber 3, the control unit 8 may control the transfer robot 1 such that the shell 201 is loaded into the cleaning chamber 3 with the opening facing downward while the pair of first gripping claws 104a1 and 104b1 grip the flange 203 from above and below.

Next, descriptions are made on a case where the transfer robot 1 unload the shell 201 from the cleaning chamber 3. In this case, the shell 201 is disposed in the cleaning chamber 3 with the opening facing downward. Therefore, the control unit 8 may control the transfer robot 1 to unload the shell 201 from the cleaning chamber 3 with the opening facing downward, while the pair of first gripping claws 104a1 and 104b1 hold the flange 203 from above and below.

As described above, in the wafer storage container cleaning apparatus 100 according to the first embodiment, the robot hand 1b as a gripping mechanism has a configuration in which the shell gripping portion 104 and the door gripping portion 105 are disposed such that the direction in which the pair of gripping claws 104a and 104b of the shell gripping portion 104 move toward and away from each other (the direction along the first straight line L1) and the direction in which the pair of gripping claws 105a and 105b of the door gripping portion 105 move toward and away from each other (the direction along the second straight line L2) are orthogonal in a top view. With this configuration, the wafer storage container cleaning apparatus 100 according to the first embodiment has an effect of efficiently cleaning the wafer storage container for the following reasons.

As described above, inside the cleaning chamber 3, the shell 201 is disposed with the opening facing downward as illustrated in FIG. 7. That is, the shell 201 is disposed with the flange 203 facing sideways. However, the shell 201 (wafer storage container 200) is loaded into the wafer storage container cleaning apparatus 100 with the opening facing sideways, that is, with the flange 203 facing upward. Therefore, in order to move the shell 201 into or out of the cleaning chamber 3, it is necessary to pivot the wrist 1e of the robot arm 1a by 90° to change the orientation of the shell 201.

Here, description is made on a case of a robot hand having a shell gripping portion and a door gripping portion in which the gripping claws 104a1 and 104b1 and the gripping claws 105a1 and 105b1 of the door gripping portion 105 are arranged on a straight line and are configured to move toward and away from each other in the same direction. In the case of such a robot hand, when the flange 203 is gripped from the up-down direction, which is a direction perpendicular to the horizontal axis 15, as in FIG. 7, one of the gripping claws (located on the lower side) of the door gripping portion 105 protrudes below the opening of the shell 201. In this case, when the shell 201 is disposed with the opening facing downward or when the shell 201 disposed with the opening facing downward is gripped, there is a risk that the gripping claw of the door gripping portion 105 will interfere with the disposition stage or the like inside the cleaning chamber 3.

Therefore, with a robot hand configured in this way, the flange 203 cannot be gripped from the up-down direction, and must be gripped from the direction parallel to the horizontal axis 15, that is, from the lateral direction.

Then, description is made on a case where the robot hand having the above-mentioned configuration grips the flange 203 from the lateral direction, and pivots the wrist 1e by 90° to change the orientation of the shell 201 by 90°. During the pivoting, a force in the torsional direction (swing direction) of a magnitude according to the inertial force of the shell 201 acts on the shell gripping portion (its constituent members, i.e., the arm block and the linear guide). A small gap exists in the movable portion such as the linear guide to enable movement, and the gap gradually expands with use, causing problems such as rattling, that is, deterioration. When such a movable portion is repeatedly subjected to the above-mentioned force, deterioration will appear earlier than in the case where it is not. That is, the lifespan will be shortened. Therefore, in the robot hand having such a configuration, in order to prevent the lifespan of the shell gripping portion from being shortened, it is necessary to suppress the pivot speed of the wrist le that changes the orientation of the shell 201. This would increase the time required to change the orientation of the shell 201, which would increase the time required to clean the wafer storage container 200, resulting in a decrease in cleaning efficiency. When the linear guides 102a and 102b were replaced with ones that were sufficiently wide, or if multiple linear guides were installed in parallel, it might be possible to suppress the decrease in lifespan even when the rotation speed was increased. However, this would increase the weight of the shell gripping portion 104, i.e., the weight of the portion that is pivoted 90°. Thus, this would hinder an increase in the pivot speed, and again, an improvement in efficiency may not be expected.

In contrast, according to the robot hand 1b of the first embodiment, as illustrated in FIG. 7, the flange 203 may be gripped from the up-down directions, which are perpendicular to the horizontal axis. Therefore, it is possible to suppress the application of a force in the torsional direction (swing direction) to the shell gripping portion 104 (its constituent members, i.e., the arm blocks 104a and 104b, and the linear guides 102a and 102b). Therefore, the above-mentioned problems with the movable portions such as the linear guides 102a and 102b are eliminated. As a result, the operation of changing the orientation of the shell 201 may be performed quickly, and the wafer storage container 200 may be cleaned efficiently.

Further, according to the wafer storage container cleaning apparatus 100 of the first embodiment, the shell gripping portion 104 that grips the shell 201 and the door gripping portion 105 that grips the door 202 may be driven by a common gripping portion driving mechanism 101, thereby simplifying the structure and reducing manufacturing costs.

### (Second Embodiment)

As described above, in the first embodiment, descriptions have been made on the case where the four distances, i.e., the distance between the end 106a1 of the connecting member 106a and the rotation center C, the distance between the end 106b1 of the connecting member 106b and the rotation C, the distance between the end 107a1 of the connecting member 107a and the rotation center C, and the distance between the end 107b1 of the connecting member 107b and the rotation center C, are identical. However, the two distances, i.e., the distance between the end 106a1 and the rotation center C and the distance between the end 106b1 and the rotation center C, and the two distances, i.e., the distance between the end 107a1 and the rotation center C and the distance between the end 107b1 and the rotation center C, may be different. That is, the stroke of the pair of gripping claws 104a1 and 104b1 may be different from the stroke of the pair of gripping claws 105a1 and 105b1. Therefore, such an embodiment will be described as a wafer storage container cleaning device according to a second embodiment. In the following description of the second embodiment, differences from the first embodiment is mainly described, and a description of the same configuration as the first embodiment may be omitted.

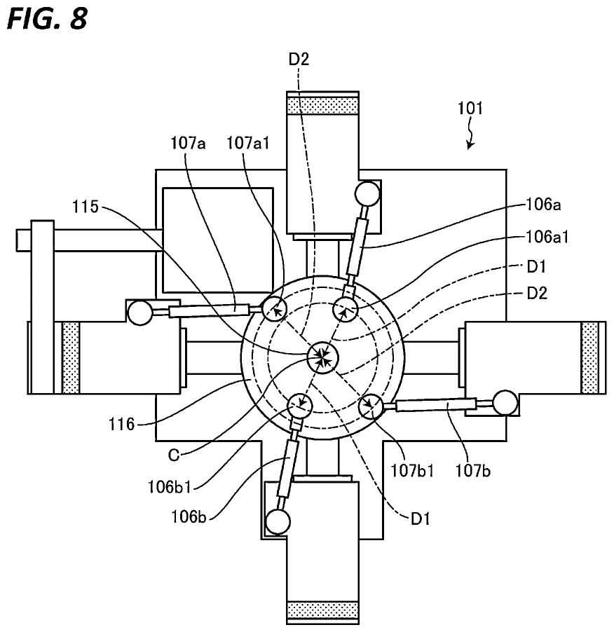

FIG. 8 is a cross-sectional view illustrating an example of the internal configuration of the robot hand according to the second embodiment. In the second embodiment, the two distances, i.e., the distance between the end 106a1 and the rotation center C and the distance between the end 106b1 and the rotation center C, and the two distances, i.e., the distance between the end 107a1 and the rotation center C and the distance between the end 107b1 and the rotation center C, are designed to be different.

As illustrated in FIG. 8, the distance between end 106a1 and the rotation center C and the distance between end 106b1 and the rotation center Care “D1.” Meanwhile, the distance between end 107a1 and the rotation center C and the distance between end 107b1 and the rotation center C are “D2.” Further, distance “D2” is longer than distance “D1.”

With this configuration, two sets of gripping claws (one set of gripping claws 104a1 and 104b1 and one set of gripping claws 105a1 and 105b1) may be opened and closed in different directions (orthogonal directions) and with different strokes by the gripping portion driving mechanism 101 with a single drive source (air cylinder 110). For example, the dimensions of the flange 203 of the shell 201 are standardized and are almost the same regardless of the type (type of manufacturer) of the wafer storage container 200. In contrast, there is no standard for the external dimensions of the door 202, and the external dimensions and shape tend to vary depending on the type of wafer storage container 200.

In such a case, in a facility where different types of wafer storage containers 200 are mixed, it is necessary to either provide separate driving mechanisms for the shell gripping portion 104 and the door gripping portion 105, or to use a single driving mechanism to make the stroke of the pair of gripping claws 104a1 and 104b1 larger to match the stroke of the pair of gripping claws 105a1 and 105b1. However, when separate driving mechanisms are provided, the structure becomes complicated and the manufacturing cost increases. Also, when a single driving mechanism is used to make the stroke of the pair of gripping claws 104a1 and 104b1 larger to match the stroke of the pair of gripping claws 105a1 and 105b1, it takes extra time to open and close the pair of gripping claws 104a1 and 104b1, which reduces efficiency.

However, in the second embodiment, such a need is not necessary, and only the stroke of the pair of gripping claws 105a1 and 105b1 of the door gripping portion 105 may be made large. Therefore, no extra time is required to open and close the pair of gripping claws 104a1 and 104b1. Therefore, the wafer storage container cleaning apparatus according to the second embodiment may perform the cleaning process more efficiently.

### (Other Modifications)

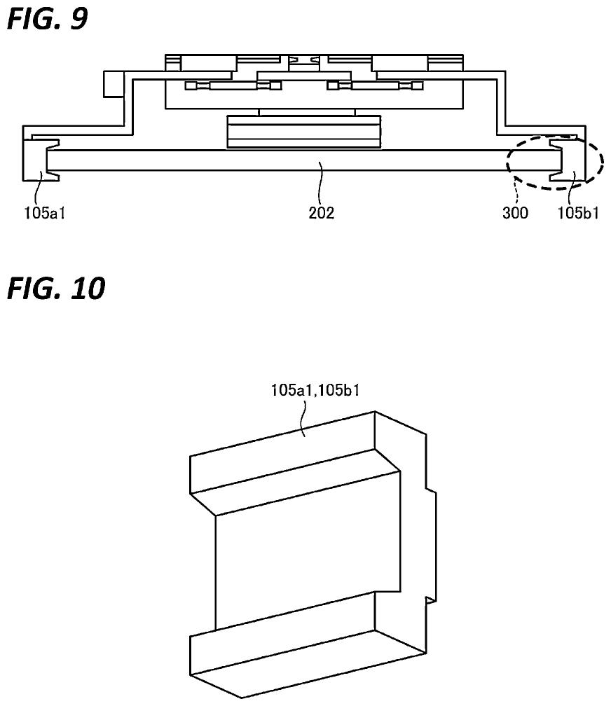

Here, the door 202 and the gripping claws 105a1 and 105b1 in each of the above-mentioned embodiments are described. FIGS. 9 to 13 are views for explaining the door 202 and the gripping claws 105a1, 105b1 in the first and second embodiments. As illustrated in FIG. 9, the pair of gripping claws 105a1, 105b1 grip the door 202 by clamping the door 202.

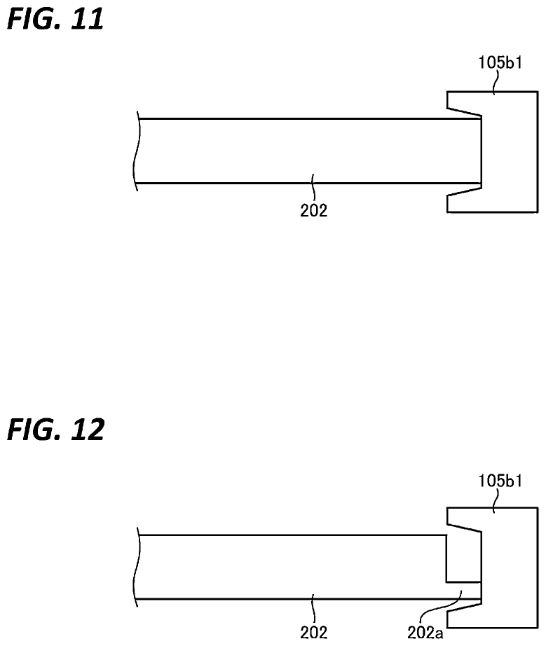

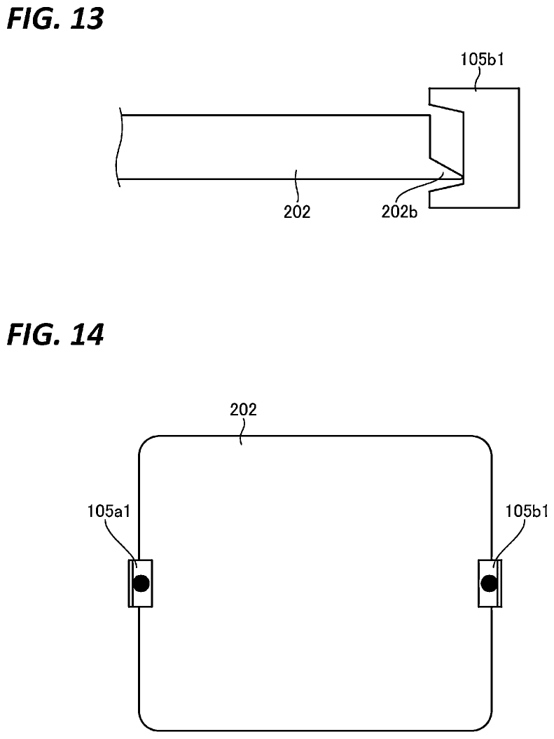

FIG. 10 is a perspective view of the gripping claws 105a1 and 105b1. As illustrated in FIG. 10, the gripping claws 105a1 and 105b1 have a substantially U-shaped shape. The surfaces of the gripping claws 105a1 and 105b, which are the central portions of the gripping claws and correspond to the bottom of the U-shape, are flat. Then, in a state where the surface of the central portion of the gripping claw 105a1 and the surface of the central portion of the gripping claw 105b1 are in contact with the outer peripheral surface of the door 202, the pair of gripping claws 105a1 and 105b1 clamp the door 202 to grip the door 202. FIGS. 11 to 13 are enlarged views of the area enclosed by the dashed line 300 in FIG. 9. As illustrated in FIG. 11, there may be no protrusions on the outer peripheral surface of the door 202. Alternatively, as illustrated in FIGS. 12 and 13 there may be protrusions 202a and 202b on the outer peripheral surface of the door 202 depending on the type of the wafer storage container 200. FIG. 14 is a view illustrating an example of a state where the pair of gripping claws 105a1 and 105b1 grip the door 202 when there is a protrusion on the outer peripheral surface of the door 202. In FIG. 14, black circles indicate a case where the gripping claws 105a1 and 105b1 are in contact with the door 202 at one point. In the example of FIG. 14, the pair of gripping claws 105a1 and 105b1 are in contact with the door 202 at two points. This may occur when the central portions of the gripping claws 105a1 and 105b1 are flat surfaces, whereas the outer peripheral surfaces of the door 202 may have undulations due to variations in processing accuracy, and a protruding portion (protrusion) is positioned opposite both gripping claws 105a1 and 105b1. In this case, the gripping of the door 202 is not stable, and the door 202 is shifted relative to the gripping claws 105a1 and 105b1.

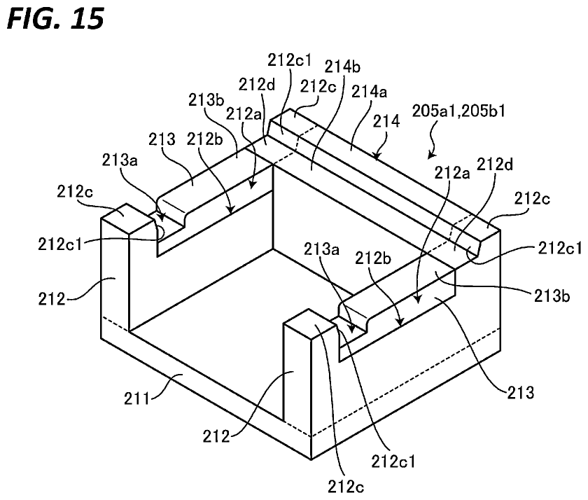

Therefore, instead of the gripping claws 105a1 and 105b1, gripping claws 205a1 and 205b1 illustrated in FIG. 15 may be used so as to stably grip the door 202 even when there is a protrusion on the outer peripheral surface of the door 202. FIG. 15 is a perspective view of the gripping claws 205a1 and 205b1 according to a modification. As illustrated in FIG. 15, the gripping claws 205a1 and 205b1 include a first member 211, a second member 212, an elastic body 213, and a third member 214.

The first member 211 is a flat plate-like member, and is a rectangular plate-like member having four sides in a plan view (when viewed from above).

A pair of second members 212 and a third member 214, each of which is a rectangular plate, are provided on the surface of the first member 211 so as to rise from each of the three sides of the first member 211. The pair of second members 212 are disposed facing each other, and the third member 214 is disposed so as to be sandwiched between the pair of second members 212. The pair of second members 212 and the third member 214 are U-shaped when viewed from above (when viewed from the direction facing the surface of the first member 211). The second member 212 has a recess 212b formed in the upper end portion (the end portion opposite the first member 211 side) 212a. In addition, protrusions 212c are formed on both ends of the upper end portion 212. The side surface of the protrusion 212c on the central side of the upper end portion 212a is formed as an inclined surface 212c1 that is inclined toward the central side. The inclined surface 212c1 functions as a guide when the gripping claws 205a1 and 205b1 grip the door 202. In addition, the recess 212b is provided with an elastic body 213 having a width equal to that of the second member 212 and a substantially rectangular outer shape. The upper end surface 213b of the elastic body 213 is formed so as to be flush with a plane 212d (a plane connected to the base end of the protrusion 212c) connected to the base end of the recess 212b. In addition, a groove 213a is formed at the end of the elastic body 213 opposite to the third member 214. When a flange-shaped protrusion is formed on the outer periphery of the door 202, the groove 213a is provided to accommodate the protrusion and to clamp the tip of the protrusion at the bottom of the groove 213a.

The third member 214 has a convex ridge portion 214a continuing to the protrusion 212c of the second member 212, and a flat surface 214b continuing to the flat surface 212d of the second member 212. Since the guide function may be fulfilled when either the convex ridge portion 214a or the protrusion 212c of the second member 212 on the third member 214 side is provided, the other may be omitted. Such first to third members 211, 212, 214 may be either formed separately or integrally.

Further, the gripping claws 205a1 and 205b1 are formed with grooves 213a for contacting the projections on the outer peripheral surface of the door 202.

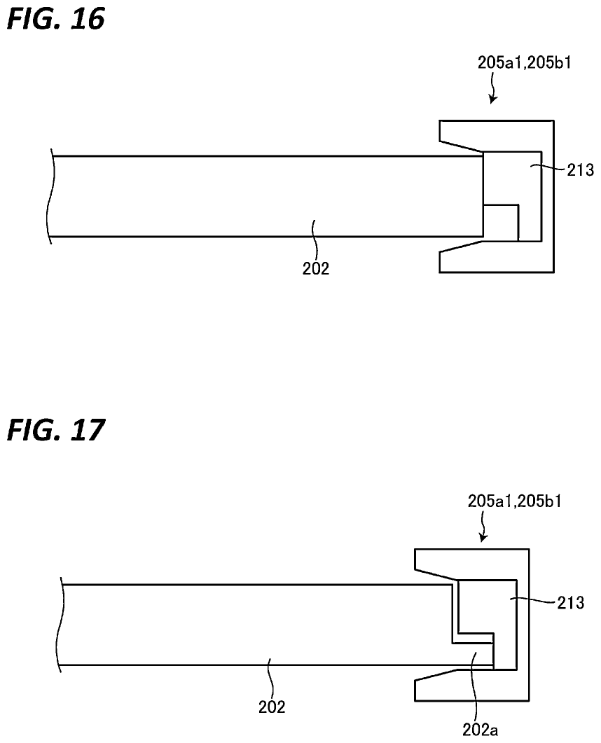

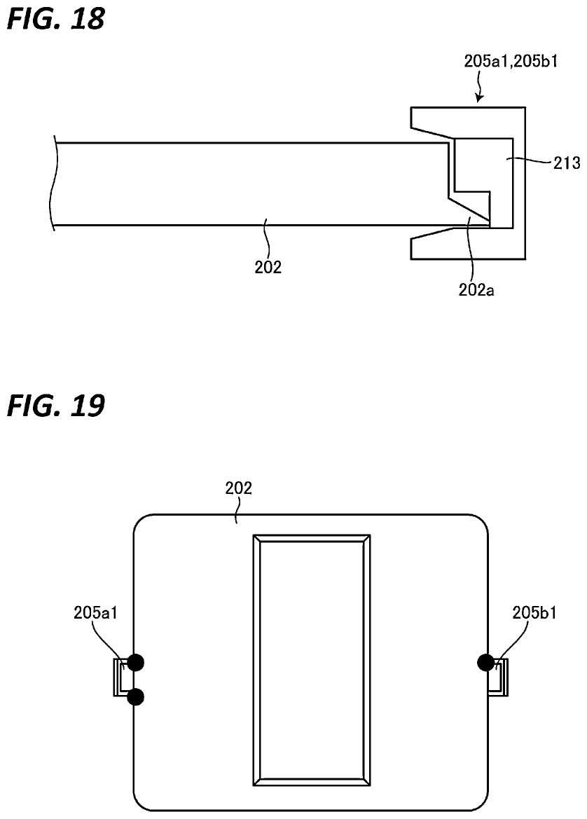

FIGS. 16 to 18 are views illustrating examples in which a pair of gripping claws 205a1 and 205b1 grip the door 202. As illustrated in FIG. 16, when the outer peripheral surface of the door 202 is flat and has no protrusions, in one gripping claw (gripping claw 205a1 or gripping claw 205b1), the upper end surfaces 213b (see FIG. 15) of the two elastic bodies 213 are in close contact with the door 202 so as not to shift the door 202. As illustrated in FIGS. 17 and 18, when the outer peripheral surface of the door 202 has protrusions 202a and 202b, in one gripping claw (gripping claw 205a1 or gripping claw 205b1), the two grooves 213a are in contact with the protrusions 202a and 202b at two points so as not to shift the door 202. FIG. 17 illustrates an example of the protrusion 202a having a square cross section, and FIG. 18 illustrates an example of the protrusion 202b having a triangular cross section. FIG. 19 is a view illustrating an example of a case where the pair of gripping claws 205a1 and 205b1 grip the door 202 when there is a protrusion on the outer peripheral surface of the door 202. In the example of FIG. 19, two black circles indicate positions where the gripping claw 205a1 is in contact with the protrusion of the door 202 at two points. Also, in the example of FIG. 19, one black circle indicates a position where the gripping claw 205b1 is in contact with the protrusion of the door 202 at one point. In this case, since the pair of gripping claws 205a1 and 205b1 are in contact with the door 202 at three points, the gripping of the door 202 is stable, and it is possible to prevent the door 202 from shifting relative to the gripping claws 205a1, 205b1.

As described above, the outer periphery of the door 202 may have undulations due to variations in processing accuracy, but since the gripping claws 205a1 and 205b1 of the modification are provided with the elastic bodies 213 at the contact portions with the door 202, undulations of a certain degree may be absorbed by the deformation of the elastic bodies 213, and the gripping claws 205a1 and 205b1 may stably grip the door 202 at a total of four points. The gripping state illustrated in FIG. 19 may occur when there is an undulation (protrusion) in the gripped area of the outer periphery of the door 202 that cannot be absorbed by the deformation of the elastic bodies 213. However, in the gripping claws 205a1 and 205b1 of this modification, the elastic bodies 213 that contact the door 202 are arranged at two separate points. Therefore, even when there is an undulation as described above, one of the elastic bodies 213 may be reliably contacted with the door 202. Therefore, unless a similar undulation exists in the other gripping area, the pair of gripping claws 205a1, 205b1 may securely grip the door 202 at a total of three points.

The first embodiment has been described with the case where the wafer storage container cleaning apparatus 100 has four cleaning chambers 3. However, the embodiment is not limited thereto, and the apparatus may have five or more cleaning chambers.

In the first embodiment, the wafer storage container cleaning apparatus 100 has been described as having four cleaning chambers 3 and two vacuum processing chambers 7. However, the embodiment is not limited thereto, and at least four processing chambers may be vacuum processing chambers 7. That is, the wafer storage container cleaning apparatus 100 may have at least four vacuum processing chambers 7, and the vacuum processing chambers 7 may be provided at the positions where the cleaning chambers 3 are provided in the first embodiment. In this case, the wafer storage container cleaning apparatus 100 may have two cleaning chambers 3, and the cleaning chambers 3 may be provided at the positions where the vacuum processing chambers 7 are provided in the first embodiment.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

What is claimed is:

1. A wafer storage container cleaning apparatus comprising:
a cleaning chamber configured to clean a wafer storage container including a shell having a hexahedral outer shape and including an opening on one surface and a gripped portion on another surface crossing the one surface with the opening, and a door detachable from the opening; and
a transfer robot including a robot hand that individually grips the shell and the door, and configured to individually load the shell and the door into the cleaning chamber and individually unload the shell and the door from the cleaning chamber,
wherein the robot hand includes:
a shell gripping portion including a pair of first gripping claws movable toward and away from each other along a first straight line, and configured to grip the gripped portion using the pair of first gripping claws; and
a door gripping portion including a pair of second gripping claws movable toward and away from each other along a second straight line intersecting the first straight line in a top view, and configure to grip the door using the pair of second gripping claws; and
wherein the cleaning chamber cleans the shell with the opening facing downward.

2. The wafer storage container cleaning apparatus according to claim 1, further comprising:
a rotating plate provided at a position where the first straight line and the second straight line intersect in a top view to be rotatable about an axis perpendicular to both the first straight lie and the second straight line;
a first guide configured to support the pair of first gripping claws to be movable in a direction along the first straight line;
a second guide configured to support the pair of second gripping claws to be movable in a direction along the second straight line;
a plurality of connectors configured to connect each of the pair of first gripping claws and each of the pair of second gripping claws to the rotating plate; and
a mover configured to move any one gripping claw of the pair of first gripping claws and the pair of second gripping claws, thereby moving all of the pair of first gripping claws and the pair of second gripping claws.

3. The wafer storage container cleaning apparatus according to claim 2, wherein a pair of end portions of a pair of connectors connected to the pair of first gripping claws on a side of the rotating plate are rotatably connected to the rotating plate at positions symmetrical with respect to a rotation center of the rotating plate, and
a pair of end portions of a pair of connectors connected to the pair of second gripping claws on the side of the rotating plate are rotatably connected to the rotating plate at positions symmetrical with respect to a rotation center of the rotating plate.

4. The wafer storage container cleaning apparatus according to claim 3, wherein a first distance between the rotation center and a position where the pair of end portions of the pair of connectors connected to the pair of first gripping claws on the side of the rotating plate are connected to the rotating plate, is different from a second distance between the rotation center and a position where the pair of end portions of the pair of connectors connected to the pair of second gripping claws on the side of the rotating plate are connected to the rotating plate.

5. The wafer storage container cleaning apparatus according to claim 4, wherein the second distance is longer than the first distance.

6. The wafer storage container cleaning apparatus according to claim 1, further comprising:
a controller configured to control the transfer robot such that, when the shell is disposed in the cleaning chamber with the opening facing downward, the shell is unloaded from the cleaning chamber with the opening facing downward while the pair of first gripping claws grip the gripped portion from above and below.

7. The wafer storage container cleaning apparatus according to claim 1, further comprising:
a controller configured to control the transfer robot such that the shell is loaded into the cleaning chamber with the opening facing downward while the pair of first gripping claws grip the gripped portion from above and below.

8. The wafer storage container cleaning apparatus according to claim 1, wherein each of the pair of second gripping claws includes:
a first member having a rectangular shape;
a second member extending upward from one side of the first member and from each of the sides opposite to the one side, the second member having a recess formed in an end portion opposite to the first member; and
an elastic body provided in the recess formed in the second member and having a groove formed therein.
